(19) United States
(12) Patent Application Publication
(10) Pub. No.: US 2022/0276414 A1
(43) Pub. Date: Sep. 1, 2022

(54) Digital Photo Frame with AG Explosion-proof Function

(71) Applicant: Shenzhen Joyhong Technology Co., Ltd, Shenzhen (CN)

(72) Inventor: Jianping Wang, Shenzhen (CN)

(73) Assignee: Shenzhen Joyhong Technology Co., Ltd, Shenzhen (CN)

(21) Appl. No.: 17/748,032

(22) Filed: May 19, 2022

(30) Foreign Application Priority Data
Apr. 12, 2022 (CN) 202210378325.8

(51) Int. Cl. G02B 5/02; H05K 5/00; A47G 1/06

(52) U.S. Cl. CPC G02B 5/021; H05K 5/0017; A47G 1/06

(57) ABSTRACT

This invention provides a new digital photo frame with AG explosion-proof function, including digital photo frame body. Digital photo frame body shell is composed of pan, middle frame and the front shell. The equipped frame's internal embedded in digital photo frame body screen AG explosion-proof membrane assembly, AG explosion-proof membrane structure by AG explosion-proof membrane, OCA glue, TP glass, cover of sensor and the LCD, AG explosion-proof film is pasted on top of TP glass cover sensor through OCA glue and TP is formed. AG explosion-proof film assembly is formed after TP is fitted with LCD of screen.

### FIELD OF TECHNOLOGY

The invention relates to the technical field of electronic photo frame auxiliary equipment, in particular to a digital photo frame with AG explosion-proof function.

### TECHNOLOGY BACKGROUND

Digital photo frame is a frame, but it is no longer used in the photos to show, but a LCD screen display, through the CPU computing, flash storage, it can get photos. And set up the shows the way, customized UI interface matching function, functional module design, is more flexible than ordinary photo frame. Also give now increasingly used digital photos a new display space.

While we use the current digital photo frame, since the complex light placed in the environment, when people watch the screen of the digital photo frame, it is easy to produce reflective phenomenon, get a bad the visual, this will reduce the people's good impression when they are use digital photo frame. Glare phenomenon not only hinders viewing, but also has a certain impact on vision, which is one of the important causes of visual fatigue. AG anti-glare technology can ensure that things can be clearly seen in the glare environment, and alleviate eye fatigue is obviously creative.

### THE CONTENT OF INVENTION

The purpose of the invention is to provide a digital photo frame with the anti-explosion-proof function, so as to solve the problem raised by the above background technology. The current digital photo frame is easy to produce reflective phenomenon and affect the visual effect when people watch the screen of digital photo frame, due to the complex light in the placement environment.

To realize the above, the invention provides the following technical scheme: AG explosion-proof function digital photo frame, including digital photo frame body, as described in the digital photo frame body shell by pan, box and the shell, referred to in the frame of internal equipped with digital photo frame body screen embedded AG explosion-proof membrane assembly of joint, as described in AG explosion-proof membrane assembly by AG explosion-proof membrane. OCA glue, TP glass cover of sensor and the LCD, AG explosion-proof film is pasted on top of TP glass cover sensor through OCA glue and TP is formed. AG explosion-proof film assembly is formed after TP is fitted with LCD of screen.

The AG explosion-proof film is an anti-glare layer with at least one layer of inner doping or uniformly plated with optical refraction material, and a spot-like frosted film structure is formed on the surface of the AG explosion-proof film.

As an optimal scheme of the invention, the AG explosion-proof film is a kind of point frosted film.

As an optimal scheme of the invention, the AG explosion-proof film is provided with an anti-glare coating on the surface.

As an optimal scheme of the invention, the screen is installed inside the bottom shell, and the front shell cover is arranged outside the middle frame and fixedly connected with the front shell.

As an optimal scheme of the invention, the bottom of the middle frame is fixedly provided with a plurality of buckle cards, and the buckle card and the bottom shell are fixedly provided with a card slot.

Compared with the prior art, the beneficial effects of the invention are:

1) The AG film with spot-like matte film structure is formed on the surface by doping in the AG explosion-proof film or evenly plating one or several layers of optical refraction material (fine particles) on the surface of the anti-glare layer, and the light scattering phenomenon can be generated by using the optical refraction material and the concave and convex structure formed. Made by the glare of light membrane and external light reflection scattering (by incident light over the surface of the concave and convex irregularly reflection), the see the light is downy, anti glare membrane can significantly reduce the reflected glare glass surface to visible light, and thus digital photo frame the harsh feeling when watching, and effectively enhance the display screen visibility, Ensure that users can clearly see the content of the digital photo frame screen display, thus increasing the use of personnel on the use of digital photo frame, and AG anti glare film can also reduce from 65% 55% of the screen glare and reflection, as well as reduce 70% of harmful blue light and glossiness, using anti glare membrane can reduce the risk of blu-ray injury and eye glare, Prevent visual fatigue, protect your eye, get your health;

2) The structure strength of AG film can be increased by setting the explosion-proof film, which can effectively prevent the anti-glare film from bursting when subjected to external forces and improve the service life of anti-glare film.

### DESCRIPTION WITH PICTURES

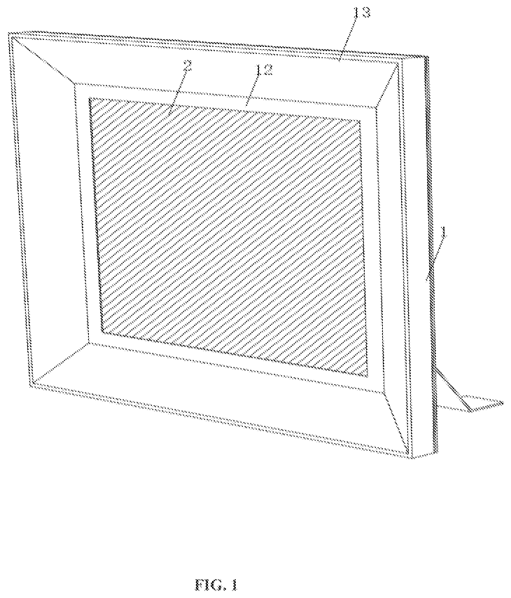

FIG. 1 is a schematic diagram of the invention.

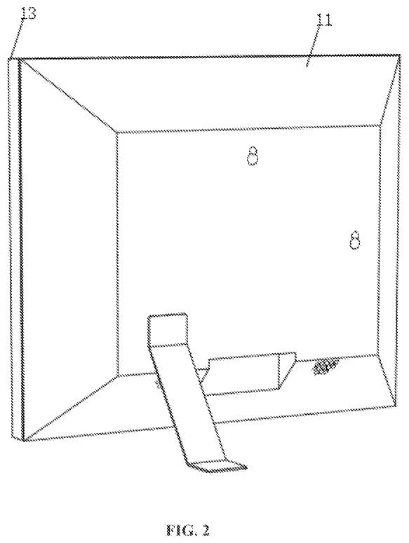

FIG. 2 is one of the structural diagrams of the invention.

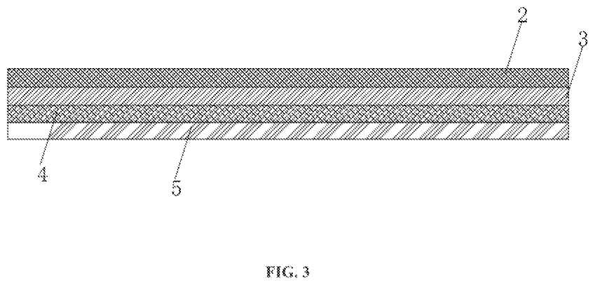

FIG. 3 is the profile diagram of AG explosion-proof film assembly of the invention;

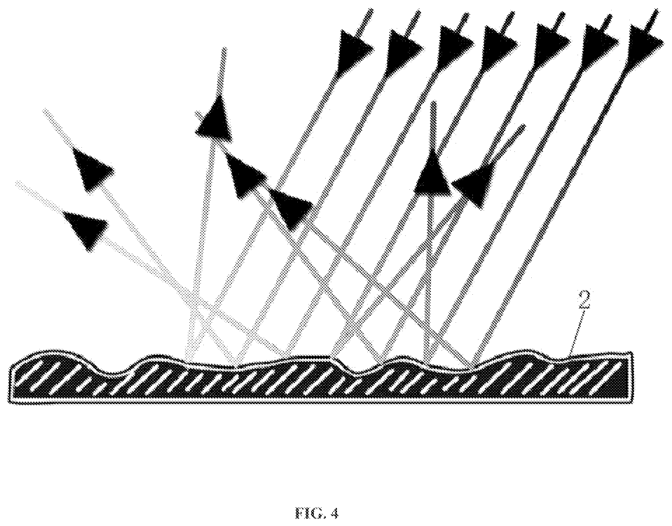

FIG. 4 is a schematic diagram of reflected light of the AG explosion-proof film of the invention.

In the picture: 1, Digital photo frame body; 11, bottom shell; 12, Middle frame; 12, buckle card; 13, Front shell; 2, AG explosion-proof film; 3, OCA glue; 4, TP glass cover plate sensor; 5, LCD.

### MODE OF CARRYING OUT THE INVENTION

The following is a clear and complete description of the technical scheme in the embodiments of the present invention in combination with the attached drawings of the embodiments of the present invention. Obviously, the described embodiments are only part of the embodiments of the present invention, not all embodiments. Based on the embodiments of the invention, all other embodiments obtained by ordinary technical personnel in the field without making creative labor belong to the scope of the invention protection.

Please refer to FIG. 1-5. The invention provides a technical solution: The digital photo frame with AG explosion-proof function includes digital photo frame body 1. The shell of digital photo frame body 1 is composed of bottom shell 11, middle frame 12 and front shell 13. The inner part of middle frame 12 is provided with AG explosion-proof film assembly which fits the screen of digital photo frame body 1. AG explosion-proof film assembly is composed of AG explosion-proof film 2, OCA glue 3, TP glass cover sensor 4 and LCD 5, in which AG explosion-proof film 2 is pasted on the top of TP glass cover sensor 4 through OCA glue 3 and formed TP, TP and LCD 5 screen after bonding to form AG explosion-proof film assembly;

The AG explosion-proof film 2 is an anti-glare layer with at least one layer doped or uniformly coated with optical refraction material, and the AG explosion-proof film 2 forms a spot-like frosted film structure on its surface, and the AG explosion-proof film 2 is one of the spot-like frosted films.

The AG explosion-proof film 2 can effectively reduce 55% glare from the screen and 65% reflection, and 70% harmful blue light and glossiness. It can also reduce the risk of blue light damage and eye glare discomfort, prevent visual fatigue and protect eye health. Increase the user's good impression of digital photo frame.

By doping or uniformly plating one or several layers of optical refractive material (fine particles) on the surface of AG explosion-proof film 2, the surface of AG explosion-proof film 2 can form a spot-like frosting film structure, using the optical refractive material and the formed spot-like frosting structure can produce scattering phenomenon of light. The light reflected through the AG explosion-proof film 2 and the external light scattering (by the incident light irregularly reflected on the concave and convex surface), resulting in soft light, AG explosion-proof film 2 can significantly reduce the glass surface of visible light reflection glare, and then reduce the glare of digital photo frame viewing.

Due to the AG film on the surface of the explosion-proof membrane 2 can be used according to actual needs, on the surface of AG explosion-proof membrane 2 multilayer processing can be done, in order to form a different texture dot frosted structure arrangement, eventually making AG 2 explosion-proof membrane can reduce the glare from the screen to 55% and 65% of reflection, as well as reduce 70% of harmful blue light and glossiness. Use an anti-glare mask to reduce blue light damage and the risk of eye glare irritation, prevent visual fatigue and protect eye health.

In order to make the AG explosion-proof film 2 have better anti-glare effect, the AG explosion-proof film 2 is coated with an anti-glare coating to further improve the anti-glare performance of the anti-glare film.

In this embodiment, the screen is installed inside the bottom shell 11, the cover of the front shell 13 is installed outside the middle frame 12 and is fixedly connected with the front shell 13, the bottom of the middle frame 12 is fixedly provided with multiple buckle cards, and the buckle cards are fixedly connected with the bottom shell 11 with card slots.

Specifically, the middle frame 12 can be quickly disassembled from the bottom shell 11 by connecting the buckle card 12 to the card slot.

As an optimal scheme of the invention, the front shell 13 and the middle frame 12 can also be fixed by hot melt column and pressed in the AG explosion-proof film fixing scheme.

This statement did not make a detailed description of the content belongs to this known professional and technical personnel in the field of existing technology, although with reference to the implementation of a detailed explanation of the invention, for technical personnel in the field of this, it still can be implemented on the foregoing cases recorded by the technical scheme, modified or to some of the technical characteristics of equivalent replacement, Any modification, equivalent substitution, improvement etc. made in the spirit and principle of the invention shall be included in the scope of protection of the invention.

1. Digital photo frame with AG explosion-proof function, including digital photo frame body (1), which is characterized in: The shell of the digital photo frame body (1) is composed of the bottom shell (11), the middle frame (12) and the front shell (13), and the middle frame (12) is embedded with the AG explosion-proof film assembly which is fitted with the screen of the digital picture frame body (1), The AG explosion-proof film assembly is composed of AG explosion-proof film (2), OCA glue (3), TP glass cover sensor (4) and LCD (5), in which AG explosion-proof film (2) through OCA glue (3) affixed to the top of TP glass cover sensor (4) and formed TP, TP and LCD (5) of the screen are fitted together to form AG explosion-proof film assembly;
The AG explosion-proof film (2) is an anti-glare layer with at least one layer of inner doping or uniformly plated with optical refraction material on the surface, and a spot-like frosted film structure is formed on the surface of the AG explosion-proof film (2).

2. According to the digital photo frame with AG explosion-proof function mentioned in claim 1, its characteristics are as follows: the AG explosion-proof film (2) is a kind of point-like frosted film.

3. According to claim 1, the digital photo frame with AG explosion-proof function, its characteristics is that the AG explosion-proof film (2) is provided with anti-glare coating on the surface.

4. According to the digital photo frame with AG explosion-proof function mentioned in claim 1, its characteristics are as follows: the screen is installed inside the bottom shell (11), and the front shell (13) is covered outside the middle frame (12) and fixedly connected with the front shell (13).

5. According to the digital photo frame with AG explosion-proof function mentioned in claim 1, its characteristics lie in that the bottom of the middle frame (12) is fixed with a plurality of buckle cards, and the buckle cards and the bottom shell (11) are fixed with card slots.
